(19) United States
(12) Patent Application Publication
(10) Pub. No.: US 2005/0056351 A1
(43) Pub. Date: Mar. 17, 2005

(54) Surface treatment method, process for producing near-field exposure mask using the method, and nanoimprint lithography mask

(75) Inventors: Tomohiro Yamada, Yokohama-shi (JP); Ryo Kuroda, Kawasaki-shi (JP)

Correspondence Address: FITZPATRICK CELLA HARPER & SCINTO, 30 ROCKEFELLER PLAZA, NEW YORK, NY, 10112, US

(73) Assignee: CANON KABUSHIKI KAISHA, TOKYO (JP)

(21) Appl. No.: 10/912,123

(22) Filed: Aug. 6, 2004

(30) Foreign Application Priority Data
Aug. 8, 2003 (JP) 289708/2003(PAT.)

(51) Int. Cl. G03F 9/00; B32B 15/04

(52) U.S. Cl. 148/525; 977/DIG. 1; 430/5; 148/565

(57) ABSTRACT

A surface treatment method includes a step of forming a metal layer on at least a part of a surface of a structural member, and a step of exposing the metal layer to a plasma based on SF₆ to effect surface treatment.

### FIELD OF THE INVENTION AND RELATED ART

The present invention relates to a surface treatment method; a process, for producing a mask for near-field exposure, using the surface treatment method; and a mask for nanoimprint lithography.

In a cooking device, a machine tool, a semiconductor fine patterning apparatus, etc., it has been desired that a structural member thereof is improved in surface soil-resistive performance or reduced in surface adsorbing power.

For this purpose, a method in which a surface energy of the structural member is lowered by surface-treating the structural member surface has been conventionally proposed as one of methods.

For example, such a coating method that a structural member surface of a cooking device is coated with a fluorocarbon resin as described in Japanese Laid-Open Patent Application (JP-A) Hei 09-28582 or a structural member surface of a machining tool is coated with a fluorocarbon resin as described in JP-A 2002-224950, has been proposed. As another method, a method of forming a Self-Assembled Monolayer (SAM) as described in M. D. Porter, T. B. Bright, D. L. Allara and C. E. D. Chidsey, “J. Am. Chem. Soc.” vol. 109 (1987) pp. 3559-, has been known, and this method has been utilized in a method of forming an SAM at a surface of a structural member of a semiconductor apparatus as described in U.S. Patent Application Publication US2002/151171A1 (corresponding to JP-A 2002-359347).

However, in the method of coating the surface of the above-described structural member with the fluorocarbon resin, the fluorocarbon resin is merely physically adsorbed onto the surface of the above-described structural member to be coated therewith, so that there is a possibility that a bonding power is relatively weak to result in a poor durability.

Further, in the case of forming the SAM on the structural member surface, the SAM is formed on the surface of structural member in a closely packed state and a large area, so that it takes a long time to form the SAM in some cases. Further, in the process of forming the SAM, a grain boundary is created, so that there is a possibility that a dense film with a uniform structure is not formed. This is liable to lead to a lowering in processing accuracy in the case of an apparatus for performing processing in a very small scale, such as a semiconductor fine patterning apparatus (device).

### SUMMARY OF THE INVENTION

An object of the present invention is to provide a surface treatment method capable of forming a low surface energy surface layer, which is more dense and durable, on a surface of a structural member etc.

Another object of the present invention is to provide a process for producing a near-field exposure mask using the surface treatment method and to provide a nanoimprint lithography mask.

According to the present invention, there is provided a surface treatment method, comprising:
a step of forming a metal layer on at least a part of a surface of a structural member, and
a step of exposing the metal layer to a plasma based on SF₆ to effect surface treatment.

In the surface treatment method, the metal layer may preferably be formed of Au, an alloy of Au and another metal or a mixture of Au and another metal. The metal layer may preferably be a thin film.

According to the present invention, there is also provided a process for producing a near-field exposure mask, comprising:
a step of preparing a substrate for supporting a mask,
a step of disposing a metal layer functioning as the mask on the substrate, and
a step of exposing the metal layer to a plasma based on SF₆ to effect surface treatment. The metal layer functions as a light blocking layer. The metal layer may preferably comprise a light blocking layer and another layer which are laminated together. The plasma based on SF₆ may preferably be generated in a vacuum chamber.

According to the present invention, there is further provided a nanoimprint lithography mask, comprising: a treatment surface which has been treated by the surface treatment method described above.

According to the present invention, it is possible to form a low surface energy surface layer, which is very thin and dense and has a high durability, on the structural member surface in a short time. By forming such an surface layer, it is possible to improve surface characteristics such as water repellency, oil repellency, and soil-resistive performance. Further, it is also possible to realize a process for producing a near-field exposure mask, the near-field exposure mask, and a nanoimprint lithography mask, which are capable of lowering a surface adsorbing power at the surface of structural member.

These and other objects, features and advantages of the present invention will become more apparent upon a consideration of the following description of the preferred embodiments of the present invention taken in conjunction with the accompanying drawings.

### BRIEF DESCRIPTION OF THE DRAWINGS

FIGS. 1(a), 1(b) and 1(c) are views for illustrating steps of forming a near-field exposure mask as an embodiment of the present invention.

FIGS. 2(a) and 2(b) are views for illustrating a lowering phenomenon of an absorbing power at the mask surface.

FIGS. 3(a), 3(b) and 3(c) are views for illustrating steps of forming a near-field exposure mask in Embodiment 1 of the present invention.

FIGS. 4(a), 4(b) and 4(c) are views for illustrating steps of forming a near-field exposure mask in Embodiment 2 of the present invention.

### DETAILED DESCRIPTION OF THE PREFERRED EMBODIMENTS

Hereinbelow, embodiments of the present invention will be described with reference to the drawings.

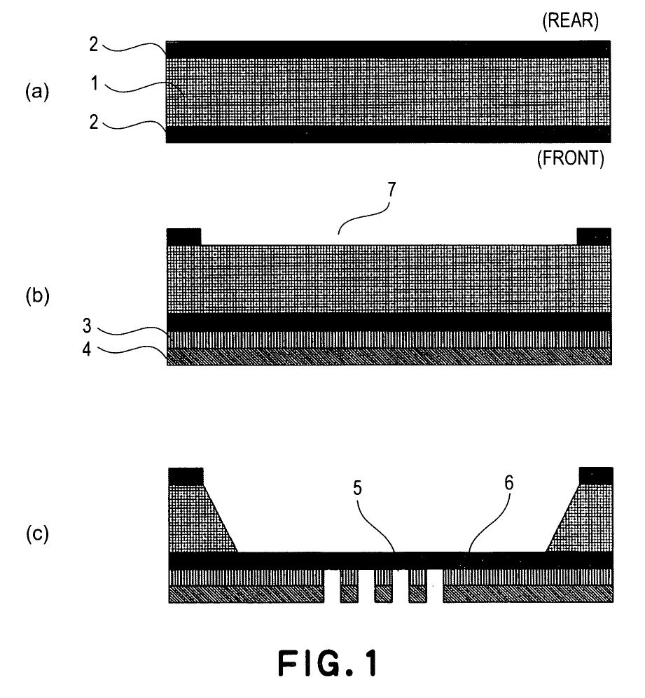

FIGS. 1(a) to 1(c) are schematic sectional views for illustrating steps of forming a mask for near-field exposure as an embodiment of the present invention.

First of all, a substrate 1 having a plane direction (100) is prepared. On both surfaces of the substrate 1, a film of silicon nitride (Si₃N₄) as a mask base material 2 is formed (FIG. 1(a)). The base material 2 is not limited to Si₃N₄ but may be other materials. On one surface (rear surface) of the base material 2 of the substrate 1, a back etching pit (opening) 7 is patterned, and on the other surface (front surface) of the base material 2 of the substrate 1, a light blocking layer 3 is formed. Thereafter, on the surface of the light blocking layer 3, a surface treatment layer 4 is formed of Au (gold) (FIG. 1(b)). The surface treatment layer 4 may also be formed of an alloy or mixture of Au and another metal.

Then, in the surface treatment layer 4 and the light blocking layer 3, a small-opening pattern 5 is formed by using a focused ion beam (FIB) processing apparatus etc.

The front surface of the resultant mask is exposed to a plasma based on SF₆ (sulfur hexafluoride) for a short time. The plasma is generated in a vacuum chamber of a dry etching apparatus, and the sample (mask) is also placed in the chamber, thus effecting surface treatment. The plasma is generated under a relatively weak etching condition including a degree of vacuum of about 10⁻⁵ Pa and a gas pressure of about 2 Pa. As a result, a surface energy of a surface treatment layer 4 is lowered, so that resultant surface characteristics of the surface treatment layer 4, such as water repellency, oil repellency, and soil-resistive performance, are improved. Further, a surface adsorbing power is also lowered. Then, the substrate 1 is subjected to crystallographic axis-anisotropic etching with KOH to form a thin film mask structure having a thin mask portion 6 (FIG. 1(c)).

According to an experiment by the inventor, the surface energy after the above described surface treatment was lowered to 21.0 dyne/cm when compared with that (50.7 dyne/cm) of a Cr film alone (which was not surface-treated) and that (48.9 dyne/cm) of an Au film alone (which was not surface-treated). Further, the absorbing power at the mask surface was also reduced.

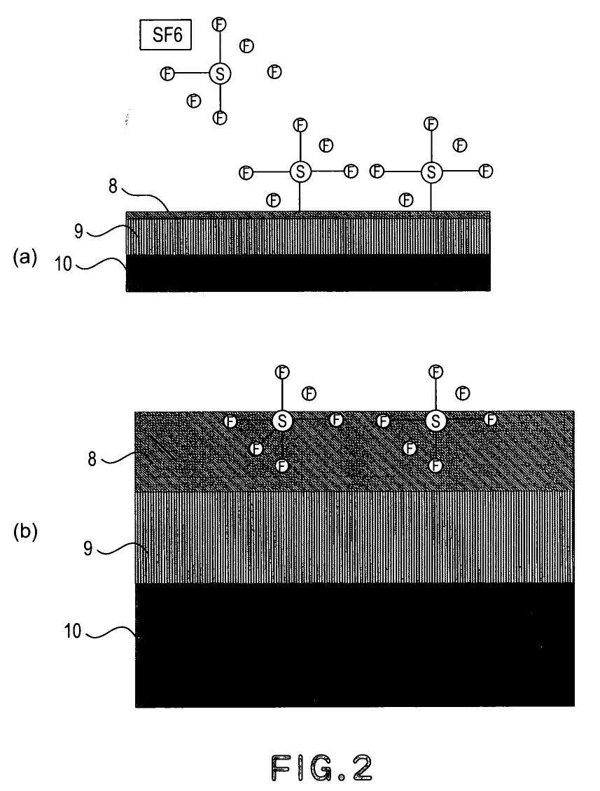

These may be attributable to a presence of SF₅ or the like, at the Au film surface, caused due to generation of a linkage of Au—S between gold and sulfur through a reaction of Au of the surface treatment layer 4 with radicals, such as SF₅ or the like in the SF₆-based plasma. There is also a possibility that SF₆ molecules, SFx radicals, F radical, etc., present in a plasma atmosphere are directly implanted in the Au layer (FIGS. 2(a) and 2(b)).

(Embodiment 1)

In this embodiment, a near-field exposure mask was prepared through the above-described production process thereof.

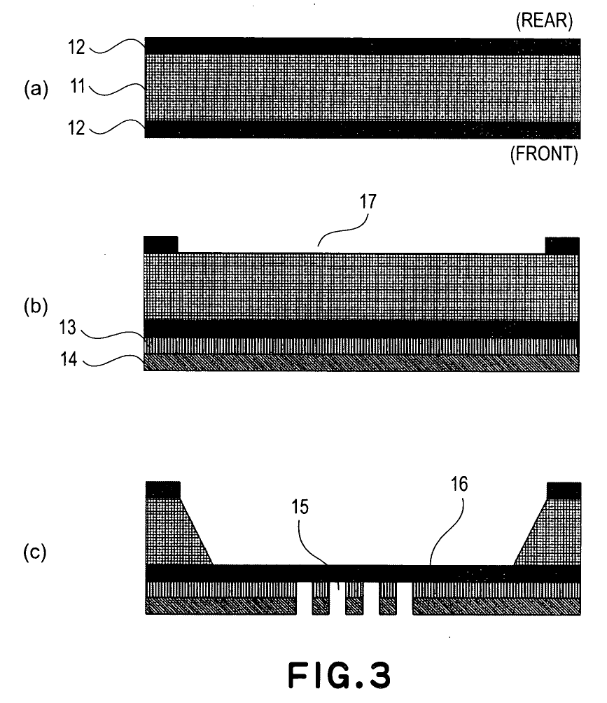

FIGS. 3(a) to 3(c) are schematic sectional views for illustrating steps of forming a mask for near-field exposure in this embodiment.

First of all, an Si (silicon) substrate 11 having a plane direction (100) was prepared. On both surfaces of the Si substrate 11, a 500 nm-thick film of Si₃N₄ as a mask base material 12 was formed by allow pressure chemical vapor deposition (LPCVD) apparatus (FIG. 3(a)). On one surface (rear surface) of the base material 12 of the substrate 11, a back etching pit (opening) 17 was patterned with CF₄, and on the other surface (front surface) of the base material 12 of the substrate 11, a 50 nm-thick light blocking layer 13 of Cr was formed. Thereafter, on the surface of the light blocking layer 13, a 10 nm-thick surface treatment layer 14 was formed of Au (FIG. 3(b)). Incidentally, the light blocking layer 13 may also be formed of a metal other than Cr.

Then, in the surface treatment layer 14 and the light blocking layer 13, a small-opening pattern 15 was formed by using an FIB processing apparatus.

The Au surface treatment layer 14 was exposed to a plasma based on SF₆ for about 5 min. Then, the substrate 11 was subjected to crystallographic axis-anisotropic etching with KOH to form a thin film mask structure having a thin mask portion 16 (FIG. 3(c)), thus preparing a mask for near-field exposure which was subjected to the surface treatment method according to the present invention.

According to this embodiment, it was possible to provide the near-field exposure mask reduced in surface energy at the mask surface. The resultant near-field exposure mask was improved in water repellency, oil repellency and soil-resistive performance, and lowered in surface-adsorbing power.

In this embodiment, the near-field exposure mask is prepared but the present invention is also applicable to other structural members requiring an adhesion and removal operation, such as a mask for nanoimprint lithography and a sliding member.

(Embodiment 2)

In this embodiment, a near-field exposure mask different from that of Embodiment 1 was prepared through the above-described production process thereof.

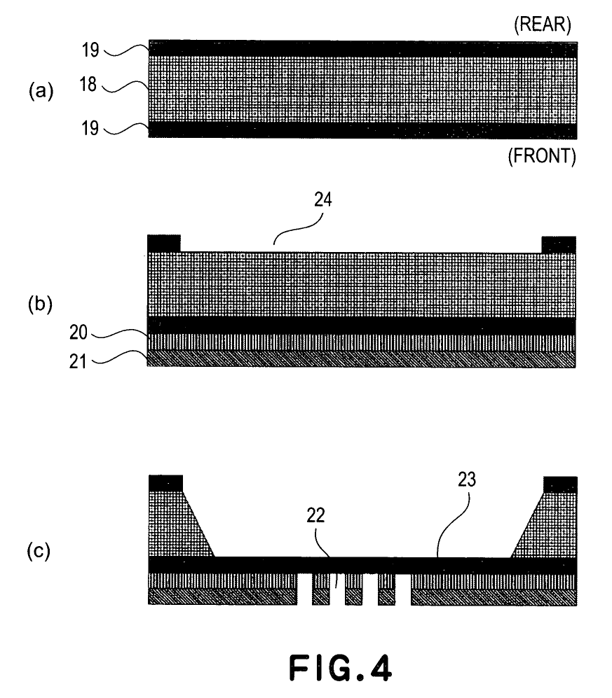

FIGS. 4(a) to 4(c) are schematic sectional views for illustrating steps of forming a mask for near-field exposure in this embodiment.

First of all, an Si (silicon) substrate 18 having a plane direction (100) was prepared. On both surfaces of the Si substrate 18, a 500 nm-thick film of Si₃N₄ as a mask base material 19 was formed by allow pressure chemical vapor deposition (LPCVD) apparatus (FIG. 4(a)). On one surface (rear surface) of the base material 19 of the substrate 18, a back etching pit (opening) 24 was patterned with CF₄, and on the other surface (front surface) of the base material 19 of the substrate 18, a 50 nm-thick light blocking layer 20 of Cr was formed. Thereafter, on the surface of the light blocking layer 20, a 10 nm-thick surface treatment alloy layer 21 was formed of an alloy of Au and Pt through co-sputtering (FIG. 4(b)). Incidentally, the light blocking layer 20 may also be formed of a metal other than Cr.

Then, in the surface treatment alloy layer 21 and the light blocking layer 20, a small-opening pattern 22 was formed by using an FIB processing apparatus.

The Au surface treatment alloy layer 21 was exposed to a plasma based on SF₆ for about 5 min. Then, the substrate 18 was subjected to crystallographic axis-anisotropic etching with KOH to form a thin film mask structure having a thin mask portion 23 (FIG. 4(c)), thus preparing a mask for near-field exposure which was subjected to the surface treatment method according to the present invention.

According to this embodiment, it was possible to provide the near-field exposure mask reduced in surface energy at the mask surface. The resultant near-field exposure mask was improved in water repellency, oil repellency and soil-resistive performance, and lowered in surface-adsorbing power.

Further, by forming the surface treatment alloy layer 21 through co-sputtering of Au and Pt, it was possible to prevent a great increase in grain size due to migration of Au, so that it became possible to ensure a relatively uniform surface energy distribution at the mask surface.

In this embodiment, the near-field exposure mask is prepared but the present invention is also applicable to other structural members requiring an adhesion and removal operation, such as a mask for nanoimprint lithography and a sliding member.

While the invention has been described with reference to the structures disclosed herein, it is not confined to the details set forth and this application is intended to cover such modifications or changes as may come within the purposes of the improvements or the scope of the following claims.

This application claims priority from Japanese Patent Application No. 289708/2003 filed Aug. 8, 2003, which is hereby incorporated by reference.

1. A surface treatment method, comprising:
a step of forming a metal layer on at least a part of a surface of a structural member; and
a step of exposing the metal layer to a plasma based on SF₆ to effect surface treatment.

2. A method according to claim 1, wherein the metal layer comprises Au.

3. A method according to claim 1, wherein the metal layer comprises an alloy of Au and another metal or a mixture of Au and another metal.

4. A method according to any one of claims 1-3, wherein the metal layer is a thin film.

5. A process for producing a near-field exposure mask, comprising:
a step of preparing a substrate for supporting a mask;
a step of disposing a metal layer functioning as the mask on the substrate; and
a step of exposing the metal layer to a plasma based on SF₆ to effect surface treatment.

6. A process according to claim 5, wherein said step of exposing the metal layer to the plasma is performed after a small-opening pattern is formed on the metal layer.

7. A process according to claim 5, wherein the metal layer functions as a light blocking layer.

8. A process according to claim 5, wherein the metal layer comprises a light blocking layer and another layer which are laminated together.

9. A process according to claim 7 or 8, wherein the metal layer comprises Cr.

10. A process according to claim 8, wherein said another layer comprises Au.

11. A process according to claim 5, wherein the plasma based on SF₆ is generated in a vacuum chamber.

12. A nanoimprint lithography mask, comprising: a treatment surface which has been treated by a surface treatment method according to any one of claims 1-3.
